(19) United States
(12) Patent Application Publication
(10) Pub. No.: US 2024/0389241 A1
(43) Pub. Date: Nov. 21, 2024

(54) CIRCUIT BOARD AND MANUFACTURING METHOD THEREOF

(71) Applicant: DAEDUCK ELECTRONICS CO., LTD., Gyeonggi-do (KR)

(72) Inventors: Min-Geun JUNG, Yeonsu-gu (KR); Min-Sung KIM, Jeonju-si (KR); Kwan-Sun YOON, Namdong-gu (KR); Han-Sung LEE, Siheung-si (KR); Young-Joo KO, Gunpo-si (KR)

(21) Appl. No.: 18/407,701

(22) Filed: Jan. 9, 2024

(30) Foreign Application Priority Data
May 21, 2023 (KR) 10-2023-0065357

(51) Int. Cl. H05K 3/46; H05K 1/11; H05K 3/24; H05K 3/34; H05K 3/40

(52) U.S. Cl. CPC H05K 3/4697; H05K 1/111; H05K 3/244; H05K 3/3452; H05K 3/4007; H05K 2201/0367

(57) ABSTRACT

The present invention discloses a circuit board consisting of a cavity with predetermined depth in the substrate, a bridge element installed in said cavity for mounting a multiple of chips on the top surface of said bridge element, and a solder resist layer all over said bridge element and the outer layer of the substrate wherein the gap in between the bridge element and the cavity wall is filled with said solder resist lamination, wherein said bridge element comprises a wiring layer in a core of organic material for electrically connecting the electrodes on the top surface to those of the bottom surface, and wherein the copper pillar is formed through the openings in the solder resist over the electrode of the bridge element.

### CROSS REFERENCE TO RELATED APPLICATION

This application claims priority under 35 USC § 119 to Korean Patent Applications No. 10-2023-0065357 (Filing Date: May 21, 2023), the contents of which are incorporated herein by reference in their entirety. The list of the prior art is the following: Korean Patent Publication No. 10-2011-0123505, Korean Patent Publication No. 10-2009-0080701, and Korean Patent Publication No. 10-2014-0114932.

### FIELD OF THE INVENTION

The present invention relates to a structure and manufacturing method of a circuit board, and more particularly of a printed circuit board (PCB). More specifically, the present invention relates a circuit board having a chip to chip interconnection means for surface-mounting the heterogenous chips.

### BACKGROUND OF THE INVENTION

Recently, as the amount of data transmission that needs to be processed on the circuit board soars in a tremendous manner, it is required to develop a high performance circuit board with improved integration density, and minimized signal loss.

The demand for a high performance circuit board gave birth to a chiplet structure that makes it possible to mount a multiple number of chips or more specifically heterogenous chips (hereinafter referred to as ‘chips’) on a single circuit board. As a consequence, a great deal of research efforts on chip to chip interconnection technology is actively underway, which allows interconnections between heterogeneous chips in a chiplet structure.

The prior art in the semiconductor industry has proposed an interposer as a means for buffering the pitch difference between the chip electrode and PCB electrode. However, the prior art has a technical limit due to its expensive fabrication process. In other words, the prior art needs to fabricate a TSV (through silicon via) with a large aspect ratio in order to electrically connect the bump on the chip side of the interposer to the bump on the opposite side of the substrate, which is technically difficult and very costly.

As another conventional technology, it was proposed to bury a silicon die in the cavity, which, however, has a technical limit because the silicon die is very much fragile and the emdedding technology is also expensive. In other words, the prior art is carried out at wafer level. The price of silicon raw materials is expensive. The production yield is lower than that of general PCB substrates. Consequently, the manufacturing cost is bound to be very high, and it has the disadvantage in that it should be produced only at wafer level.

### SUMMARY OF THE INVENTION

Accordingly, the present invention is designed to solve the problems of the interposer and the wafer-level embedding according to the conventional technology. The purpose of the present invention is to provide a low-cost, high-yield circuit board manufacturing method and a structure to achieve interconnection between chips of fine pitch by employing the traditional material and technology which is used in the package industry without using high-cost and low-yield silicon die interposer of the prior art.

In order to achieve the goal of the present invention, this invention discloses a circuit board consisting of a cavity with predetermined depth in the substrate, a bridge element installed in said cavity for mounting a multiple of chips on the top surface of said bridge element, and a solder resist layer all over said bridge element and the outer layer of the substrate wherein the gap in between the bridge element and the cavity wall is filled with said solder resist lamination, wherein said bridge element comprises a wiring layer in a core of organic material for electrically connecting the electrodes on the top surface to those of the bottom surface, and wherein the copper pillar is formed through the openings in the solder resist over the electrode of the bridge element.

A first embodiment of manufacturing method of a circuit board according to the present invention comprises steps of (a) fabricating a cavity in the substrate; (b) applying an adhesive on the bottom surface of the cavity; (c) mounting a bridge element on the bottom surface of the cavity through said intervening adhesive and adjusting the height level with pressure on the adhesive in such a way that the top surface of the bridge element is aligned to that of the outer layer of the substrate; (d) laminating a solder resist all over the surface of the bridge element and the outer layer of the substrate; (e) selectively removing the solder resist on the outer layer of the substrate to form first openings; (f) selectively removing the solder resist on the bridge element to form second openings; (g) forming copper pillars in the first openings and in the second openings by electroplating; and (h) mounting chips either on the bridge element or on the bridge element and outer surface of the substrate in such a way that the electrodes of the chips are in contact with the copper pillars.

A second embodiment of the present invention steps of (a) fabricating a cavity in the substrate; (b) applying an adhesive on the bottom surface of the cavity; (c) mounting a bridge element on the bottom surface of the cavity through said intervening adhesive and adjusting the height level with pressure on the adhesive in such a way that the top surface of the bridge element is aligned to that of the outer layer of the substrate; (d) laminating a solder resist all over the surface of the bridge element and the outer layer of the substrate; (e) selectively removing the solder resist on the outer layer of the substrate to form first openings; (f) selectively removing the solder resist on the bridge element to form second openings; (g) forming copper pillars in some of the first openings of a first region and in the second openings by electroplating, (h) forming microballs in the other first openings of a second region, and (i) mounting chips either on the bridge element or on the bridge element and outer surface of a first region of the substrate in such a way that the electrodes of the chips are in contact with the copper pillars.

The present invention makes it possible to realize a chip to chip interconnection on the circuit board without employing an interposer simply by installing an organic bridge with adhesive, printing a solder resist, and forming a copper pillars for mounting chips.

### BRIEF DESCRIPTION OF THE DRAWINGS

FIGS. 1a to 1j are cross-sectional drawings illustrating the fabrication method according to a first embodiment of the present invention.

FIGS. 2a to 2k are cross-sectional drawings illustrating the fabrication method according to a second embodiment of the present invention.

### DETAILED DESCRIPTION OF THE INVENTION

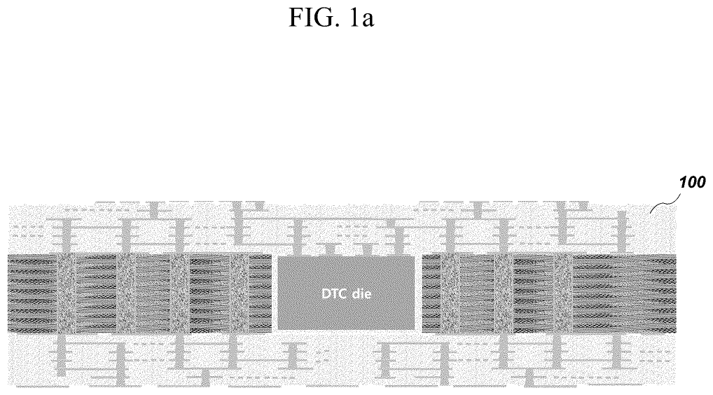

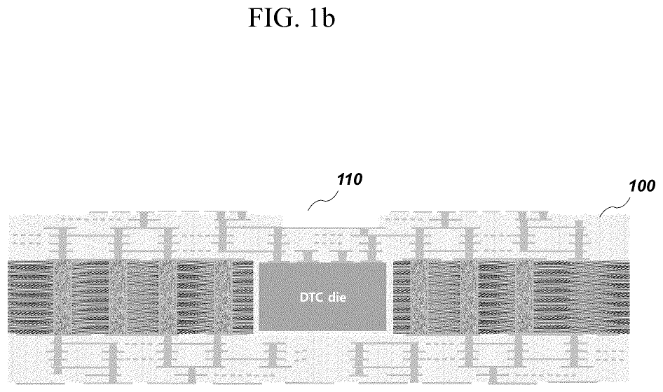

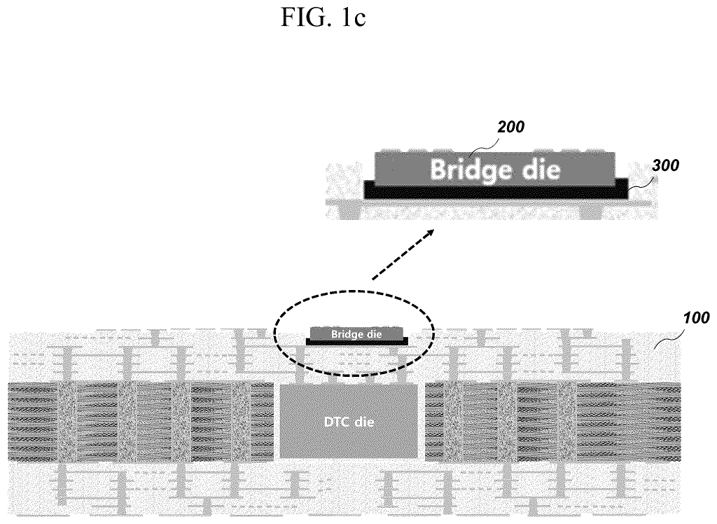

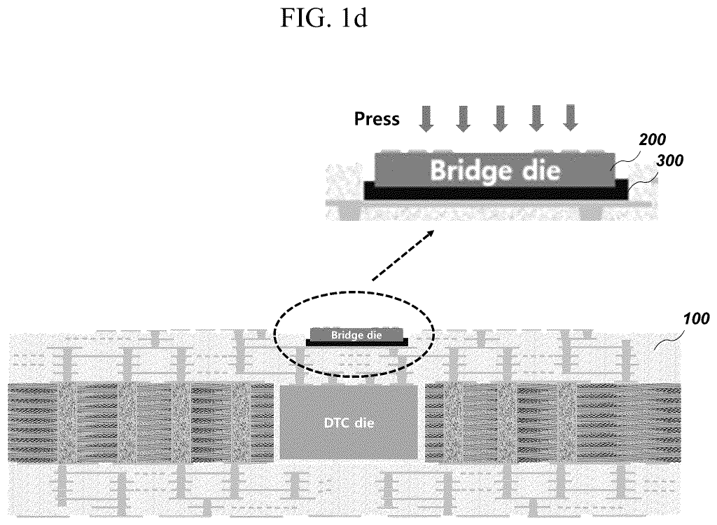

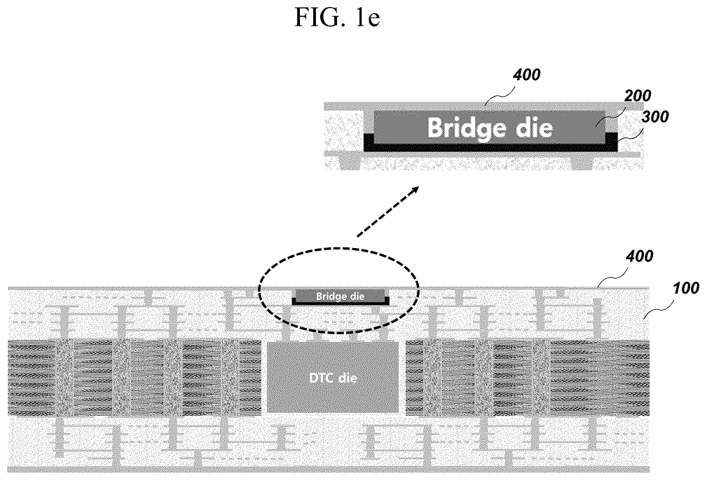

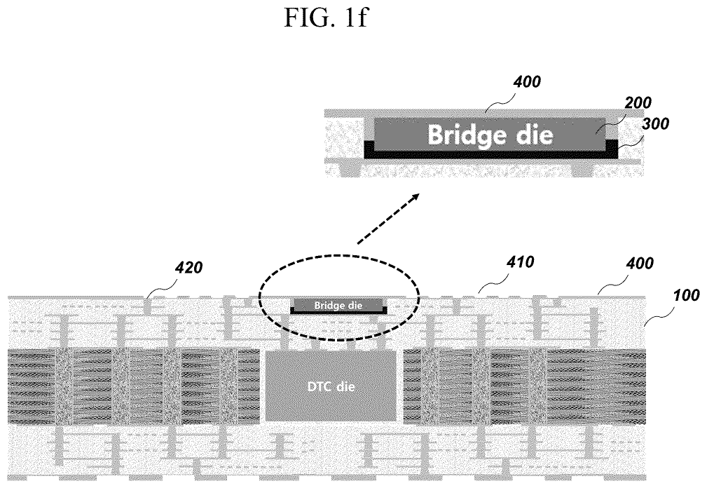

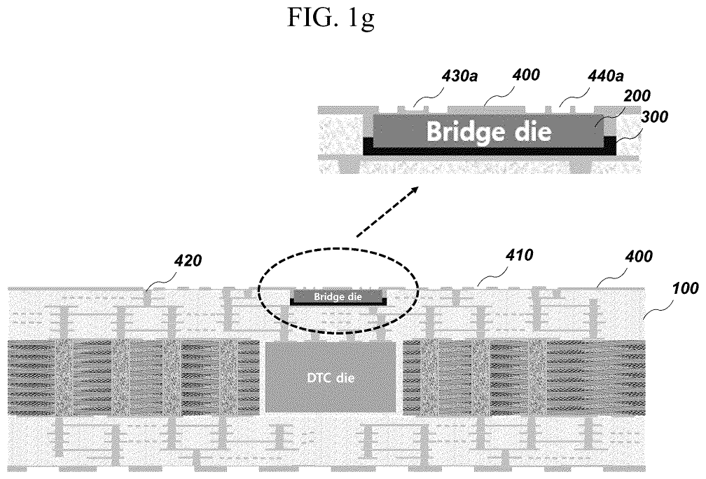

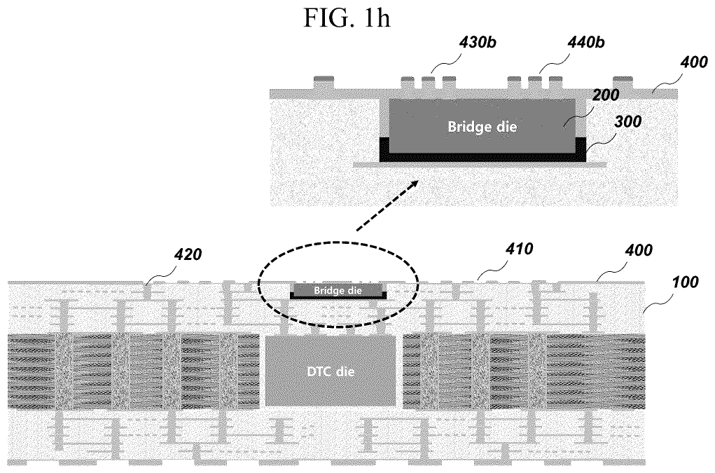

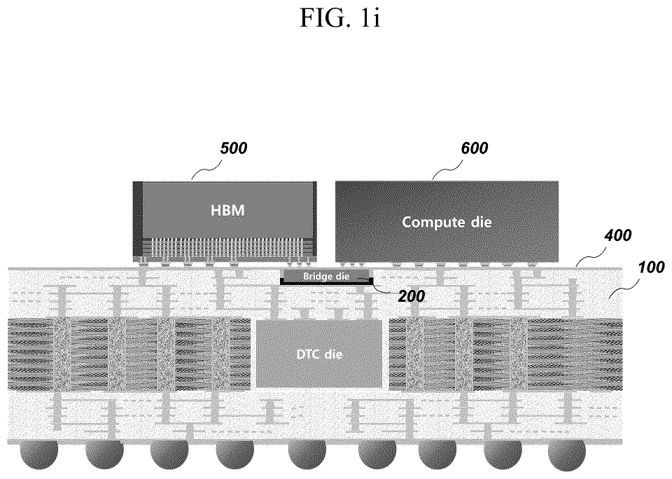

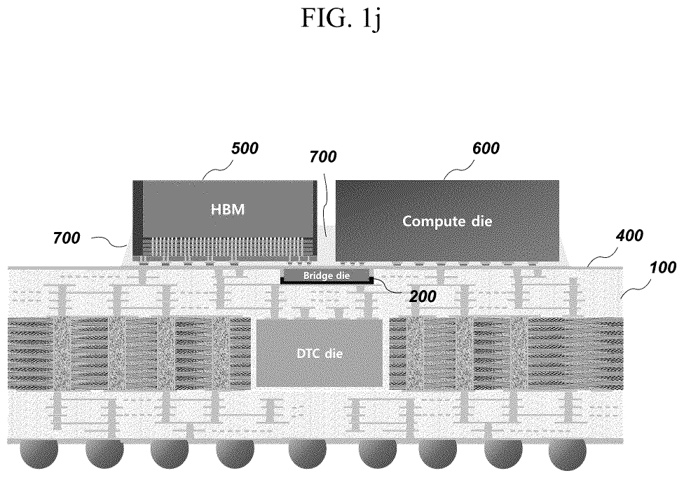

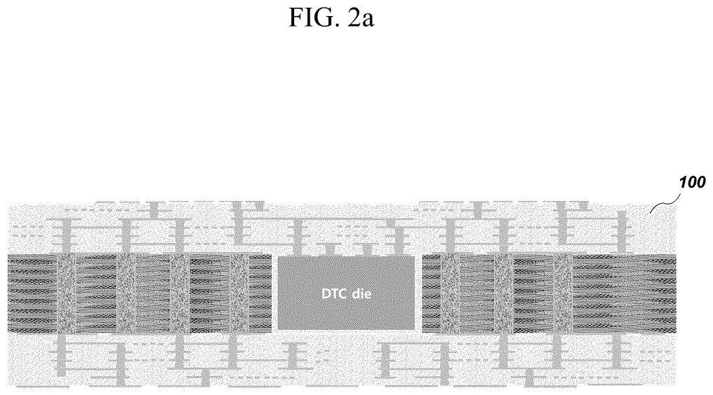

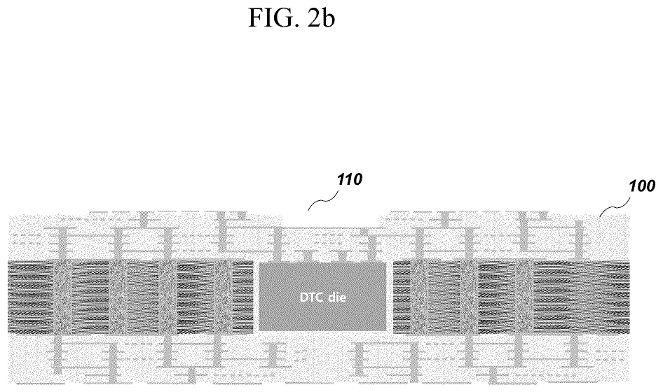

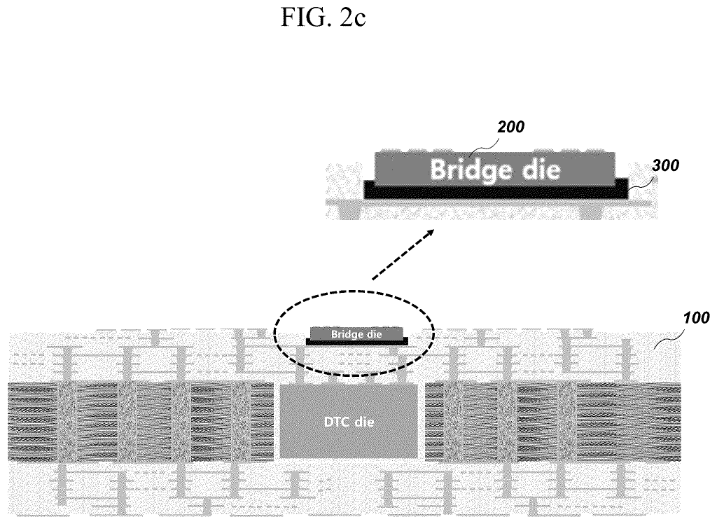

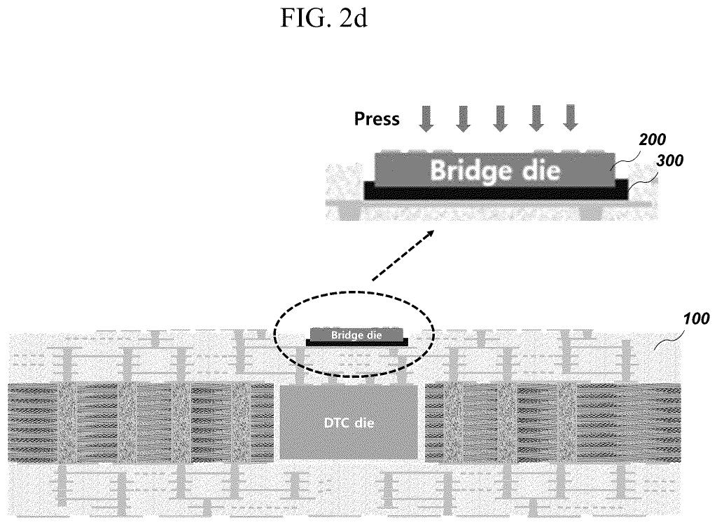

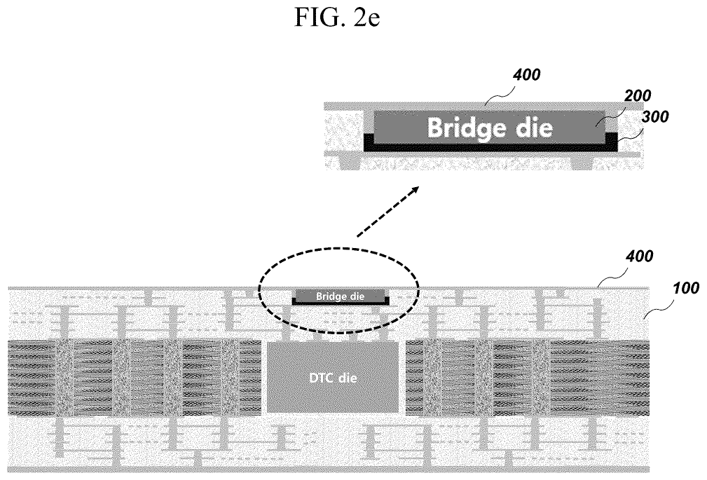

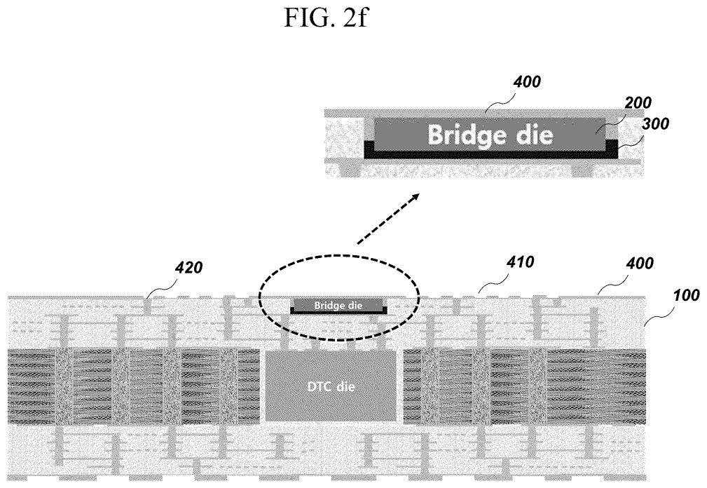

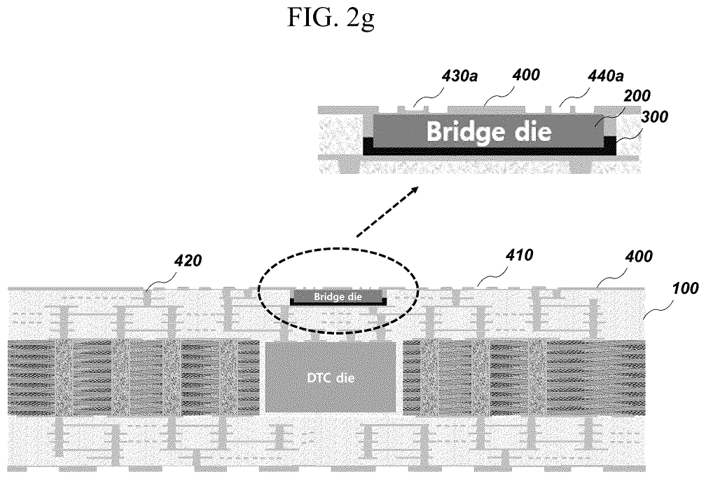

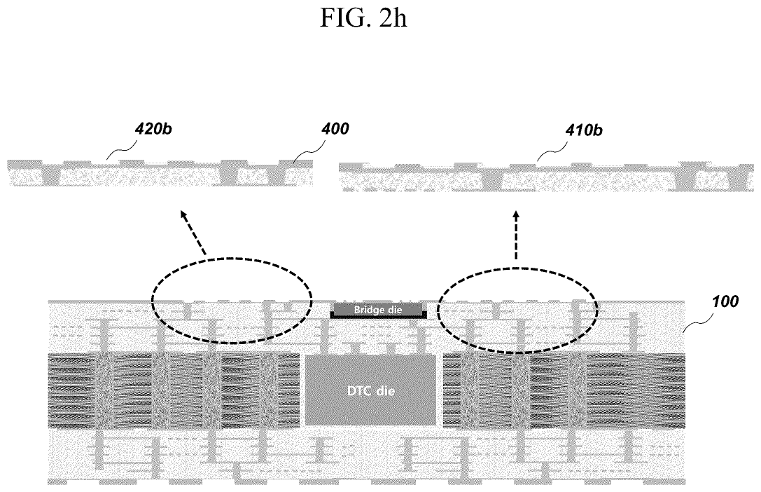

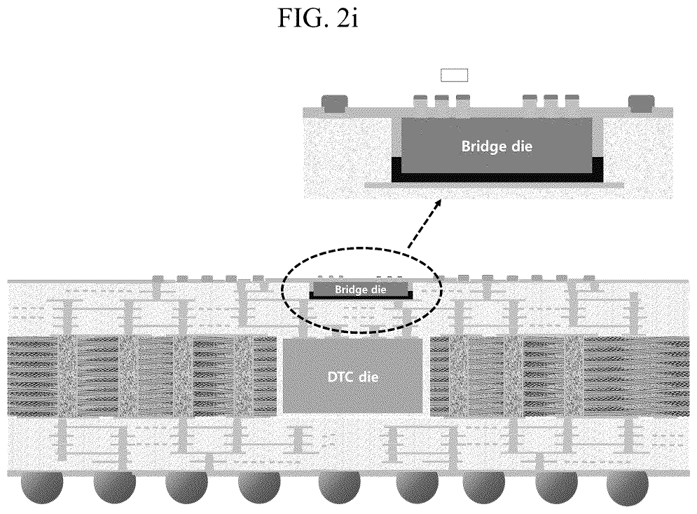

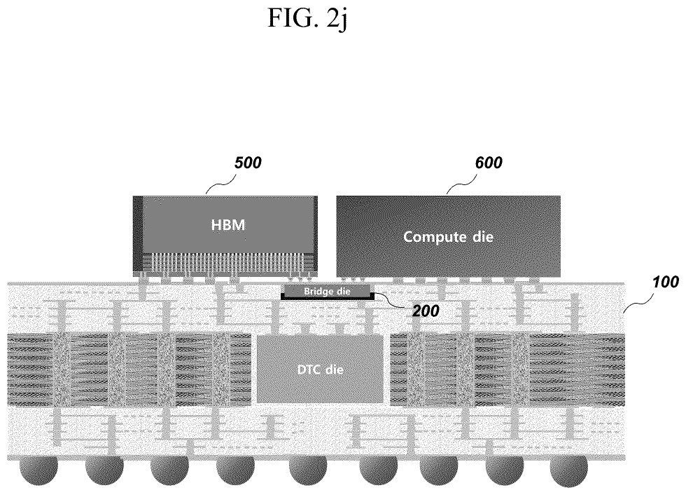

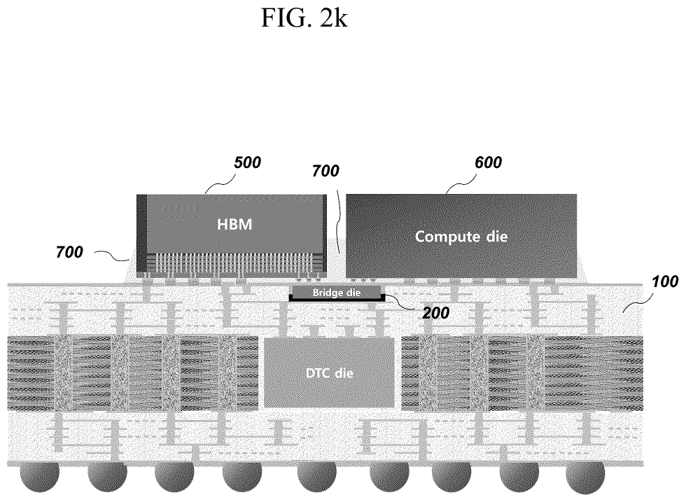

Detailed descriptions will be made on preferred embodiments and constitutional features of the fabricating method in accordance with the present invention with reference to attached figures from FIG. 1 and FIG. 2.

FIGS. 1a to 1j are cross-sectional drawings illustrating the fabrication method according to a first embodiment of the present invention.

Referring to FIG. 1a, an outer layer circuit 100 is shown as a good embodiment of the present invention. The cross-sectionak drawing shown in FIG. 1a exemplifies a circuit board wherein a multi-layer circuit is stacked on both sides of the outer layer of the core in which a die or chip (DTC die) is embedded in the substrate. However, it is not recommended to limit the circuit board illustrated in FIG. 1a as a starting material for manufacturing a circuit board according to the present invention.

In other words, as a preferred embodiment for the starting material in accordance with the present invention, copper-cladded laminate (CCL), resin-coated copper (RCC), PREPREG, Ajinomoto ABF resin, an epoxy impregnated with glass fiber can be used, or a substrate consisting of a multi-layer copper circuit can be used as a starting material.

Referring to FIGS. 1a and 1B again, a cavity 110 with a predetermined height thickness is formed in the substrate 100 having an outer layer circuit. It is preferred that the cavity should be manufactured through drilling, and that the depth of the cavity 110 formed on the substrate 100 corresponds to the thickness of the bridge element 200 to be embedded.

In the following, the device for interconnection between heterogeneous chips (chip to chip interconnection bridge) shall be called the bridge element 200, and the bridge element 200 is equipped with a plurality of copper pads on the upper surface so that the heterogeneous chips can be surface mounted (e.g., flip chip mounting or BGA mounting), and wiring layer for electrically connecting the surface copper pads with each other.

As a preferred embodiment of the bridge element 200 according to the present invention, a silicon die or resin-based PREPREG, ABF resin from Ajinomoto Co., Ltd., Japan, or an organic bridge which is made of an insulation material impregnated with glass fiber for stiffness and copper-plated layer can be employed.

Subsequently, referring to FIG. 1c, the adhesive 300 is applied to the bottom surface of the cavity 110 and the bridge element 200 is pushed in to settle on the adhesive 300. DAF (Dry Adhesive Film) may be used as a good embodiment for the adhesive 400 according to the present invention.

Referring to FIG. 1d, in the process of settling the bridge element 200 according to the present invention on the adhesive 300, if the height level of the installed bridge element is not aligned to that of the outer layer of the substrate, we can adjust the height level by pressing or lifting the bridge element 200 on the adhesive.

Referring to FIG. 1e, after the bridge element 200 is settled in the cavity 110, the solder resist 400 is printed for lamination. Unlike the prior art, the present invention does not employ resin or ABF in fixing the bridge element in the cavity, and employ the solder resist which is commonly used for the surface treatment of the printed circuit board manufacturing. As a preferred embodiment, the solder resist is coated both on the bridge element and the outer layer of the substrate simultaneously in a single process, thereby having the effect of simplifying the fabrication process.

Subsequently, a dry film (not shown in the figure) is coated on the surface of the laminated solder resist layer, followed by a series of photolithographic process comprising a photo, development, and selective etching for pattern transfer. Thereby we can form an opening in the solder resist film 400 according to the circuit pattern and we can expose selectively the surface of the outer copper layer 410 and 420.

At this time, as a good embodiment according to the present invention, as shown in FIG. 1f, we can make openings only in the solder resist on the outer layer of the substrate via a photolithographic pattern transfer process. Further, in the meanwhile we can make openings in the solder resist on the upper surface electrode 430a and 440a of the bridge element 200 (depicted as a circular dotted line) by laser drilling.

As another good embodiment of the present invention, referring to FIG. 1g, both the outer layer circuit 410, 420 of the substrate and the upper surface electrode 430a, 440a of the bridge element are all covered with dry film (not shown), and a series of pattern transfer processes such as exposure, development, etching under the mask pattern can be performed to make openings simultaneously (SR Open).

Referring to FIG. 1h, we can make copper pillars 430B, 440B in the openings on the exposed surface both of the upper electrode of the bridge element and the outer layer of the substrate via electroplating. As a good embodiment of the present invention, tin (Sn) plating may be added to the surface of the surface of the copper pillars. Here, copper pillars are also called copper bumps in the PCB industry.

Referring to FIG. 1i, multiple heterogeneous chips 500, 600 are surface-mounted (e.g., various electrical connection methods such as flip chips may be applied), and thereby electrical connections are made to the outer layer of copper circuit of the substrate 100 and the electrodes of the bridge element 200 according to the present invention.

Referring to FIG. 1j, the final EMC molding 700 and reflow process are carried out in an effort to to firmly attach the chip 500, 600 to the substrate 100.

FIGS. 2a to 2j are schematic drawings showing a circuit board manufacturing method according to a second embodiment of the present invention. In the second embodiment of the present invention, the process from FIG. 2a to FIG. 2g is the same as the process of FIG. 1a to FIG. 1g of the first embodiment. However, we should note that there is a difference in the approach for making copper pillars on the surface of the outer layer as shown in FIG. 2h and FIG. 2i.

Referring to FIG. 2h, the manufacturing method according to the second embodiment of the present invention selectively make SR openings only in the outer copper layer 410b, 420b of the substrate, not on the bridge element in the cavity area, followed by ENEPIG gold plating.

Referring to FIG. 2i, the manufacturing method according to the second embodiment of the present invention is characterized by copper-plating only on the electrode of the upper surface of the bridge element to form a copper pillar, and to form a microball on the surface copper of the outer layer of the gold-plated pillars on the substrate.

Referring to FIG. 2J, a plurality of heterogeneous chips 500, 600 are surface-mounted (e.g., flip chips and other well-known electrical connection methods may be applied). The copper circuit of the outer layer of the substrate 100 and the bridge structure 200 according to the present invention are electrically connected. Referring to FIG. 2K, the final EMC molding 700 and reflow process are carried out to firmly attach the chip 500 and 600 to the substrate 100.

The foregoing has been a rather extensive improvement of the features and technical advantages of the present invention in order to better understand the scope of the patent claims of the invention to be described later. The additional features and advantages that constitute the patent claims of the present invention will be detailed below. It should be recognized by those skilled in the field of the present that the concept and specific embodiments of the present invention that have been disclosed can be readily used as the basis for the design or modification of other structures to perform purposes similar to the present invention.

Further in addition, the invention concept and embodiment disclosed in the present invention may be used by skilled persons in the field of the art as a basis for modifying or designing a different structure to accomplish the same purpose of the present invention. In addition, such modified or altered equivalence structure by a person skilled in the field of technology is subject to various evolutions, substitutions, and variations within the scope of the patent claims, as long as it does not go beyond the idea or scope of the invention described above. it will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A manufacturing method of a circuit board, comprising steps of:
(a) fabricating a cavity with a predetermined depth in the board;
(b) applying an adhesive on the bottom surface of the cavity;
(c) installing a bridge element on the adhesive and adjusting the height level in such a way that the top surface of the installed bridge element is aligned to that of the outer layer of the substrate;
(d) forming an SR layer by pasting a solder resist all over the bridge element and the outer layer of the substrate;
(e) making SR openings in the SR layer on the outer layer of the substrate;
(f) making SR openings in the SR layer on the bridge element;
(g) forming copper pillars in the SR openings by electroplating; and
(h) mounting chips in such a way that the electrodes of the chips are in contact with the copper pillars.

2. A manufacturing method of c circuit board, comprising steps of:
(a) fabricating a cavity with a predetermined depth in the substrate;
(b) applying an adhesive on the bottom surface of the cavity;
(c) installing a bridge element on the adhesive and adjusting the height level in such a way that the top surface of the installed bridge element is aligned to that of the outer layer of the substrate;
(d) forming an SR layer by pasting a solder resist all over the bridge element and the outer layer of the substrate;
(e) making SR openings in the SR layer on the outer layer of the substrate;
(f) making SR openings in the SR layer on the bridge element;
(g) forming copper pillars in the SR openings on the bridge element and partly in the SR openings on the outer layer of the substrate by electroplating;
(h) forming microballs partly in the SR openings on the outer layer of the substrate; and
(i) mounting chips in such a way that the electrodes of the chips are in contact with the copper pillars.

3. The method as set forth in claim 1, characterized in that the adhesive of the step (b) is DAF (Dry Adhesive Film).

4. The method as set forth in claim 1, characterized in that said bridge element comprises the electrode on top surface for electrical connection to chips and a wiring layer in the resin-based substrate.

5. The method as set forth in claim 1, characterized in said SR openings of the step (f) are made either by laser drill or by photolithography comprising mask printing, photo-exposure for pattern transfer, develop, and etch processes.

6. The method as set forth in claim 1, characterized in that said SR openings of the step (e) are made by photolithography comprising mask printing, photo-exposure for pattern transfer, develop, and etch processes.

7. The method as set forth in claim 1, characterized in that said copper pillars are bumps which are formed by Cu/Ni/Sn electroplating.

8. The method as set forth in claim 2, characterized in that the adhesive of the step (b) is DAF (Dry Adhesive Film).

9. The method as set forth in claim 2, characterized in that said bridge element comprises the electrode on top surface for electrical connection to chips and a wiring layer in the resin-based substrate.

10. The method as set forth in claim 2, characterized in that said SR openings of the step (f) are made either by laser drill or by photolithography comprising mask printing, photo-exposure for pattern transfer, develop, and etch processes.

11. The method as set forth in claim 2, characterized in that said SR openings of the step (e) are made by photolithography comprising mask printing, photo-exposure for pattern transfer, develop, and etch processes.

12. The method as set forth in claim 2, characterized in that prior to the step of (h) gold (Au) electroplating for finish-treatment is performed in the SR openings on the outer layer of the substrate

13. A circuit board having chips mounted on the surface, consisting:
a cavity with predetermined depth in the board;
a bridge element comprising an electrode on the top surface and a wiring layer in the resin-based organic substrate, which is installed on the bottom surface of said cavity via adhesive, wherein the height level of the surface of the installed bridge element is made to be aligned with that of the outer layer of the circuit board by adjusting downward pressure on the adhesive;
a solder resist layer printed all over said bridge element and the outer layer of the substrate wherein the gap in between the bridge element and the cavity wall is filled with solder resist by lamination,
characterized in that the electrodes of the chips are in contact with the electrodes of the bridge element through the copper pillars formed in the openings of the solder resist layer.

14. The circuit board as set forth in claim 13, further characterized in that the electrodes of the chips are in contact with the copper pads of the outer layer on the substrate through the copper pillars formed in the openings of the solder resist layer.

15. The circuit board as set forth in claim 13, further characterized in that the electrodes of the chips are in contact with the copper pads, which is finished with Au electroplating treatment, of the outer layer on the substrate through microballs formed in the openings of the solder resist layer.
